(19) United States
(12) Patent Application Publication
(10) Pub. No.: US 2003/0068885 A1
(43) Pub. Date: Apr. 10, 2003

(54) Method of forming a contact plug for a semiconductor device

(76) Inventor: Woo Seock Cheong, Kyoungki-do (KR)

Correspondence Address: LADAS & PARRY, 224 SOUTH MICHIGAN AVENUE, SUITE 1200, CHICAGO, IL, 60604, US

(21) Appl. No.: 10/034,085

(22) Filed: Dec. 28, 2001

(30) Foreign Application Priority Data
Oct. 8, 2001 (KR) 2001-61886

(51) Int. Cl. H01L 21/00; H01L 21/44

(52) U.S. Cl. 438/674; 438/675

(57) ABSTRACT

A method for forming a contact plug of a semiconductor device having the steps of forming an insulating layer on a silicon substrate, forming a contact hole in the insulating layer, forming an inorganic layer on an inner sidewall surface of the contact hole, and forming a selective conductive plug in the contact hole, including over a surface of the inorganic layer.

### BACKGROUND OF THE INVENTION

1. Field of the Invention

The present invention relates generally to a method of fabricating a semiconductor device. More particularly, the present invention relates to a method of forming a contact plug suitable for highly integrated semiconductor devices.

2. Description of the Prior Art

Recently, the selective epitaxial growth (SEG) of silicon has been valued highly as an advantageously available technology for use in fabrication of semiconductor integrated circuit devices in view of the reduction in cell size, the simplification of process steps and the improvement of electrical characteristics.

As is widely known in the art, a silicon contact plug of the semiconductor device has been conventionally formed by depositing amorphous silicon in a contact hole and then performing a chemical mechanical polishing (CMP) process for planarization.

Such a conventional method is, however, confronted with a serious problem of how to reduce contact resistance in a design requirement for contact plugs having dimensions of less than 0.16 microns.

Therefore, to solve problems related to gap-fill property as well as contact resistance due to reduced cell size, the selective silicon epitaxial growth technology is accepted as an alternative method for forming the silicon contact plug.

In addition, since the selective silicon epitaxial growth technology does not require a conventional process step, such as the CMP process or a silicon recess etch process, for plug separation, it provides the added advantage of simplifying the manufacturing processes.

However, there are several problems to be solved in applying the selective silicon epitaxial growth technology to the formation of the silicon contact plug.

One of the problems is how to guarantee the etch selectivity of pattern material used for forming a window for the selective epitaxial growth.

Another problem is that a surface of a nitride layer is exposed when a self-aligned contact (SAC) etch is employed for a cell active area.

Furthermore, the selective silicon epitaxial growth technology may cause different defects due to thermal stress or various facet generation aspects according to the pattern material.

Generally, in a low-pressure chemical vapor deposition (LPCVD) process, it is difficult to provide etch selectivity to nitride material at a temperature less than 850° C., in contrast to oxide material.

Therefore, in order to obtain sufficient etch selectivity the growth rate should be lowered, but thereby incurring increased thermal growth.

One of conventional methods of forming a contact plug for a semiconductor device is described hereinafter with reference to accompanying drawings.

FIGS. 1 to 4 are cross-sectional views showing the steps of a conventional method of forming a contact plug for a semiconductor device.

As illustrated in FIG. 1, a gate electrode 3 is formed on a silicon substrate 1, and then sidewall spacers 5 are formed on lateral sides of the gate electrode 3.

Next, although it is not illustrated in the drawings, impurity junction regions are formed in the silicon substrate 1 at both sides of the sidewall spacers 5 by implanting impurities therein.

Thereafter, an interlayer dielectric layer 7 is deposited over the silicon substrate 1 including the gate electrode 3 and the sidewall spacers 5.

Referring to FIG. 2, the interlayer dielectric layer 7 is then masked and patterned by means of a photolithography technique, so that a plug contact hole 9 is formed in the interlayer dielectric layer 7, thereby exposing the impurity junction regions (not shown).

Next, as depicted in FIG. 3, an amorphous silicon layer 11 is deposited on the interlayer dielectric layer 7 including over the plug contact hole 9, thereby filling the plug contact hole 9.

Referring to FIG. 4, the amorphous silicon layer 11 is then subjected to a CMP process or a silicon recess etch process. As a result, a contact plug 11a is formed in the contact hole 9, the plug 11a being electrically connected to the impurity junction regions (not shown) Unfortunately, the above-described conventional method has several drawbacks, especially in a case of forming contact holes and associated contact plugs having a high aspect ratio or if the semiconductor design requires contact plugs having dimensions of less than 0.16 micron.

One drawback is that the conventional method requires a greater number of unit processes, such as the deposition of amorphous silicon and the separation of plugs, causing increased costs in production.

Additionally, since the tube type LPCVD apparatus commonly used for the deposition of silicon does not have in-situ cleaning functionability, it is impossible to prevent an undesirable natural oxide layer from being produced at the interface between the cell and the plug. This may increase the contact resistance of a polysilicon plug by three times more than that of a plug by means of the selective silicon epitaxial growth.

Another drawback encountered in using the conventional method is a poor gap-fill property resulting from the reduced size and increased aspect ratio of the contact hole during the deposition of silicon.

Furthermore, the conventional method for forming the plug may degrade device characteristics because, as compared with the case of the selective silicon epitaxial growth, phosphorus in heavily doped amorphous or polycrystalline silicon is more actively diffused during subsequent annealing processes.

Another conventional method for forming a plug of a semiconductor device is described briefly hereinafter but is not illustrated in any accompanying drawings.

According to this other conventional method, an interlayer dielectric layer is deposited using a nitride material over a silicon substrate having a gate electrode and an impurity junction region.

The interlayer dielectric layer is then selectively patterned to form a contact hole exposing the impurity junction region.

Thereafter, a silicon plug of selective epitaxial growth is grown in the contact hole, while maintaining an etch selectivity to the interlayer dielectric layer of nitride.

Such conventional method employing the selective epitaxial growth of silicon can reduce the contact resistance and simplify the process of forming the plug. However, when the LPCVD process is used, the conventional method using the selective silicon epitaxial growth needs a high content of hydrochloric acid (HCl) so as to obtain a sufficient etch selectivity on a surface of the nitride layer. Inevitably, this causes a reduction in the growth rate of the selective silicon epitaxial growth.

Moreover, since nitride material has a thermal coefficient of expansion (TCE) greater than that of silicon, the selective silicon epitaxial growth may lead to defects therein due to variation of temperature during the manufacturing process.

Alternatively, when an ultrahigh vacuum-chemical vapor deposition (UHV-CVD) process is used, it is difficult to guarantee the process margin with respect to the surface of the nitride layer.

Furthermore, at a temperature less than about 900° C., regions for maintaining the etch selectivity are reduced in the nitride layer by approximately ten times than that in a corresponding oxide layer.

In addition, the UHV-CVD process also has a high defect ratio in a pattern of the nitride layer, a difficulty in maintaining the etch selectivity to the nitride layer during in-situ doping, and a low growth rate.

These may bring about an increase in thermal budget and degradation in device characteristics. Moreover, overgrowth in the selective silicon epitaxial growth may be generated according to density and shape of the cell pattern, thereby causing undesirable problems during any subsequent CMP processes for removing the interlayer dielectric layer.

### SUMMARY OF THE INVENTION

It is therefore an object of the present invention to provide a method of forming an improved contact plug for a high-integrated semiconductor device.

Another object of the present invention is to provide a method of forming a contact plug for a semiconductor device capable of simplifying fabrication processes of the semiconductor device by employing a selective silicon epitaxial growth technique.

Still another object of the present invention is to provide a method of forming a contact plug for a semiconductor device capable of reducing the contact resistance of the contact plug.

Furthermore, another object of the present invention is to provide a method of forming a contact plug for a semiconductor device capable of reducing production cost by minimizing the amount of a silicon source used for gap-fill of the silicon plug.

Still another object of the present invention is to provide a method of forming a contact plug for a semiconductor device, capable of the reducing time required for forming the contact plug by accelerating the growth of silicon at an inorganic layer on a sidewall surface of the contact hole.

These and other objects in accordance with the present invention are attained by a method of forming a contact plug for a semiconductor device, the method comprising the steps of forming an insulating layer on a silicon substrate, forming a contact hole in the insulating layer, forming an inorganic layer on an inner sidewall surface of the contact hole, and forming a selective conductive plug in the contact hole including over a surface of the inorganic layer.

### BRIEF DESCRIPTION OF THE DRAWINGS

FIGS. 1 to 4 are cross-sectional views showing the steps of a conventional method for forming a contact plug of a semiconductor device.

FIGS. 5 to 8 are cross-sectional views showing the steps of a method for forming a contact plug of a semiconductor device according to an embodiment of the present invention.

FIG. 9 is a TEM photograph for showing a cross-section of a contact plug formed according to an embodiment of the present invention.

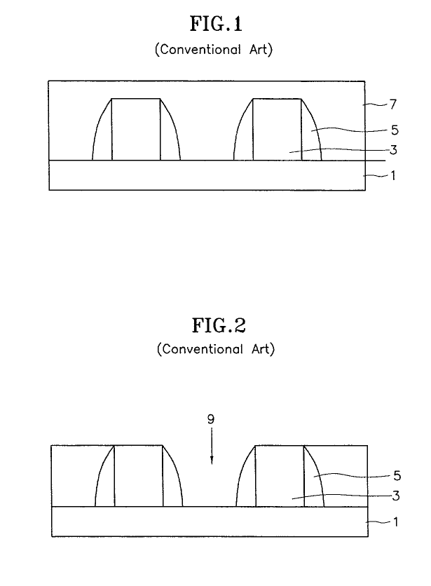

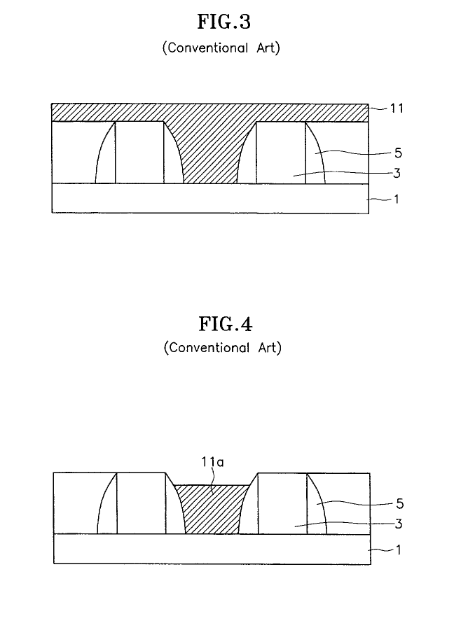

### DETAILED DESCRIPTION OF THE INVENTION

The present invention now will be described more fully with reference to accompanying drawings, in which preferred embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art.

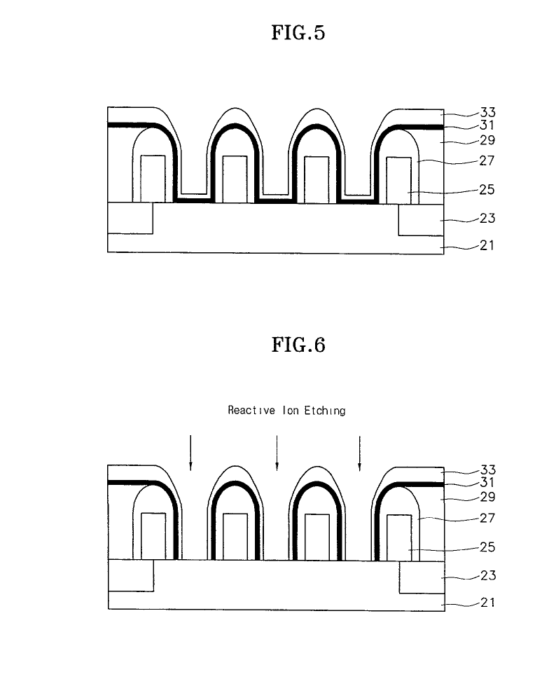

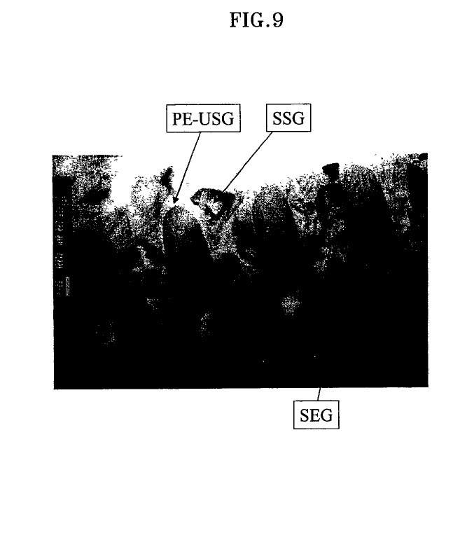

FIGS. 5 to 8 are cross-sectional views showing the steps of a method of forming a contact plug for a semiconductor device according to an embodiment of the present invention, and FIG. 9 is a TEM photograph for showing a cross-section of a contact plug manufactured using the steps according to the described embodiment of the present invention.

Referring to FIG. 5, a trench isolation layer 23 is formed in a silicon substrate 21 thereby defining a device active region and a device isolation region.

Next, a gate insulating layer (not shown) and a gate structure 25 are sequentially formed on the device active region of the silicon substrate 21. Thereafter, an insulating layer such as an oxide layer or a nitride layer is deposited over the silicon substrate 21 and the gate structure 25, and then selectively removed by using an anisotropic etching process. As a result, an insulating spacer 27 is formed on upper and lateral sides of the gate structure 25.

Subsequently, impurity junction regions (not shown) are formed in the silicon substrate 21 under both sides of the insulating spacer 27.

Next, another insulating layer 29, such as an interlayer dielectric layer, is deposited over an entire resultant structure, including over the insulating spacer 27. The insulating layer 29 is then selectively patterned to form a contact hole (not designated by reference numerals) exposing a portion of the silicon substrate 21 between the adjacent insulating spacers 27.

Thereafter, an inorganic layer 31, acting as an anti-reflective coating (ARC) layer, and an oxide layer 33, such as a plasma enhanced undoped silicate glass (PE-USG) layer, are sequentially deposited over the entire resultant structure, including over the contact hole. For the inorganic layer 31, an amorphous silicon layer or a complex of an oxide layer and a nitride layer may be used. The inorganic layer 31 has a thickness of about 10 to about 100 Å, while the PE-USG oxide layer 33 has a thickness of about 300 to about 1000 Å. Here the step coverage of the PE-USG oxide layer 33 should be less than 50%.

The deposition of the inorganic layer 31 is performed under the following conditions; namely, a SiH₄ flow rate of between 50 and 100 sccm, a N₂O flow rate of between 100 and 300 sccm, a He flow rate of between 1000 and 3000 sccm, a pressure of between land 10 Torr, a temperature of between 300 and 450° C., and a power of between 50 and 150 Watts.

On the other hand, the deposition of the PE-USG oxide layer 33 is performed by using a source gas selected among SiH₄, N₂O, O₂ and H under a pressure of between 0.1 and 100 Torr, a temperature of between 350 and 600° C., and a power of between 100˜1000 Watts.

Thereafter, as shown in FIG. 6, a reactive ion etching (RIE) process is performed. The RIE process selectively removes the inorganic layer 31 and the PE-USG oxide layer 33 from the bottom surface of the contact hole, thereby opening a silicon window to the contact hole.

The RIE process is carried out by using NF₃, O₂ and He gas plasma complying with the following conditions; a NF₃ flow rate of between land 50 sccm, an O₂ flow rate of between 30 and 300 sccm, a He flow rate of between 100 and 2000 sccm, a pressure of between 1 mTorr and 10 Torr, a temperature ranging from room temperature to 200° C., and a power of between 1 and 200 Watts.

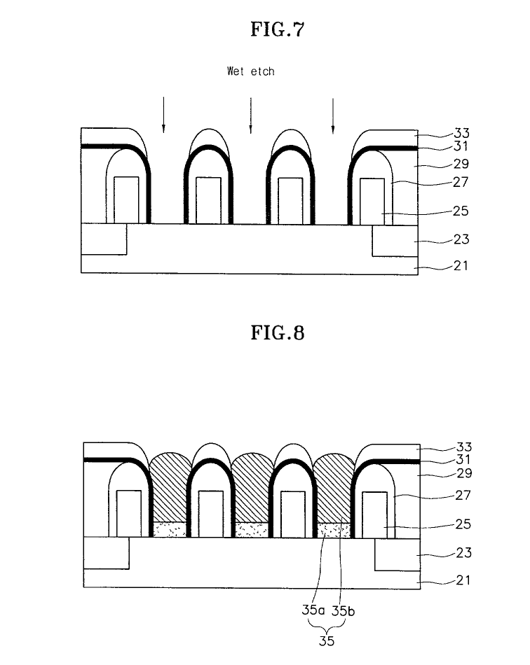

Next, as depicted in FIG. 7, the PE-USG oxide layer 33 is selectively removed again from the sidewall surfaces of the contact hole by means of a wet etching process. Therefore, the inorganic layer 31 on the sidewall surface of the contact hole is exposed, and the PE-USG oxide layer 33 remains only on an upper portion of the inorganic layer 31 lying on the gate structure 25. The remaining PE-USG oxide layer 33 has preferably a thickness of about 200 to 400 Å.

The wet etching process for the PE-USG oxide layer 33 is performed at a temperature of between 50 and 100° C., while using a HF solution diluted with deionized water of between 50 and 500 times. For example, when the PE-USG, layer with 50% step coverage, is deposited to a thickness of about 600 Å, the wet etching process makes a target of between 300 and 400 Å.

Thereafter, an in-situ cleaning process is performed as hydrogen gas only is supplied into a chamber. The in-situ cleaning process is done before forming a selective silicon plug in a subsequent step, particularly, by using the LPCVD process. Furthermore, the in-situ cleaning process is carried out in the same chamber as that in which the selective silicon plug is formed. Upon an increase in temperature, the in-situ cleaning process removes any undesirable oxide layer on the substrate surface.

Considering process time and thermal budget, the cleaning process uses preferably a rapid thermal processing (RTP) technique. However, a hydrogen baking technique can be alternatively used. In the RTP, the temperature rises rapidly to approximately 950° C. and then falls sharply to a specific temperature appropriate for selective silicon growth, namely, between 550 and 630° C. When the temperature rises or falls, a ramping rate of the temperature change is maintained at between 10˜100° C./second.

If the hydrogen baking process is used, the resulting structure is annealed in between 5 to 30 minutes under hydrogen ambience with a hydrogen flow rate of between 5 and 150 slm, a pressure of between 1 and 200 Torr, and a temperature of between 750 and 950° C.

Next, as illustrated in FIG. 8, a selective silicon plug 35 is grown in the contact hole within which the inorganic layer 31 and the silicon substrate 21 are exposed. The growth of the selective silicon plug 35 is done by selectively using an LPCVD process or UHV-CVD process.

When the LPCVD process is used, a DCS-H₂—HCl or MS-H₂—HCl gas system, where DCS and MS mean respectively a dichlorosilane gas and a monosilane gas, based on a Si—H—Cl system can be preferably adopted.

The DCS-H₂—HCl gas system is performed under the following conditions, namely, a temperature of between 750 and 950° C., a pressure of between 5 and 150 Torr, a DCS flow rate of between 0.1 and 1 slm, a HCl flow rate of between 0.1 and 1 slm, and a H₂ flow rate of between 30 and 150 slm.

On the other hand, the MS-H₂-HCl gas system is performed under the following conditions; namely, a temperature of between 750 and 950° C., a pressure of between 5 and 150 Torr, a MS flow rate of between 0.1 and 1 slm, a HCl flow rate of between 0.5 and 5 slm, and a H₂ flow rate of between 30 and 150 slm.

Additionally, as common in-situ doping conditions, H₂ gas including between 1 and 10% PH₃ gas is supplied with a flow rate of between 0.1 and 1.5 slm. A target of silicon epitaxial growth is determined to be between 60 and 100% of a gap between adjacent gate structures. For example, when that gap is 1000 Å, the selective silicon plug is grown to between 600 and 1000 Å.

As a result, a single crystalline silicon 35a is selectively grown on the surface of the silicon substrate 21, while a polycrystalline silicon 35b is selectively grown on the inorganic layer 31 on the sidewall surface of the contact hole. Thus the single crystalline silicon 35a and the polycrystalline silicon 35b are combined to fill the contact hole with an excellent gap-fill property.

Instead of LPCVD process, the UHV-CVD process can be alternatively used for the growth of the selective silicon plug 35.

In this case, the nucleus of silicon begins to be created during the deposition for the selective epitaxial growth. A maximum thickness of the selective epitaxial growth permitting the creation of the silicon nucleus, is a so-called incubation thickness, in general, of between 800 and 1200 Å.

Adding chlorine gas can increase the thickness of silicon epitaxial growth. This may, however, give rise to an unfavorable decrease in growth rate. While the incubation thickness is utilized to attain a maximum growth rate, the addition of chlorine gas is used to improve process margin.

The UHV-CVD process employs a Si₂H₆—Cl₂—H₂ gas system in which each gas has a flow rate of between 1 and 10 sccm, 0 and 5 sccm, or 0 and 20 sccm. Additionally, the UHV-CVD process is performed under in-situ doping conditions by using H₂ gas including between 1 and 10% PH₃ gas. Here, the temperature ranges from between 600° C. to 800° C., and a pressure varies from between 1 mTorr to 50 mTorr.

Forming of the selective silicon plug is carried out by means of an UHV-CVD apparatus for single wafer processing or a tube type UHV-CVD apparatus for silicon epitaxial growth.

Furthermore, adding GeH₄ in the deposition of the selective silicon plug 35 improves the selectivity to the PE-USG oxide layer 33 and also increases the growth rate. Preferably, GeH₄ has a flow rate of up to 10 sccm, and the growing thickness of the plug 35 reaches up to between 60 and 100% of the width of the contact hole.

As fully described hereinbefore, the method of forming a contact plug for a semiconductor device according to the present invention has the following advantages and effects.

By the method of the present invention, the insulating spacer acts as a self-aligned contact pattern and is covered with the PE-USG oxide layer at its upper portion and the inorganic ARC layer at its lateral portion. This improves the selectivity margin in the selective epitaxial growth and thereby increases the growth rate of the contact plug.

Since the inorganic ARC layer on the sidewall of the insulating spacer serves to accelerate the growth of silicon, there exists a strong likelihood that the selective epitaxial growth technology can be reliably applied via simplified processes. Thus, the target of selective polysilicon growth can be considerably decreased, and thereby the manufacturing process can be shortened. Furthermore, formation of facets may be inhibited as a result of the acceleration of the silicon growth on the inorganic layer.

In the present invention even though the target of selective epitaxial growth is reduced, no problem of filling the contact hole is encountered. In addition, the possibility of an electrical bridge due to cell patterns is reduced because there is little probability of overgrowth.

According to the present invention, the formation of the contact plug by means of the selective epitaxial growth technology remarkably reduces the contact resistance in comparison with conventional methods using a tube polysilicon plug. For example, the contact resistance can be reduced by at least 30%.

Additionally, the PE-USG oxide layer above the gate structure serves to lower the height of the mask nitride layer, therefore the self-aligned contact process can be improved.

The method of the present invention may greatly increase the chance of applying a UHV-CVD process to the formation of the contact plug. Although the UHV-CVD process is generally weak in selectivity and growth rate, as compared with the LPCVD process, the UHV-CVD process can increase productivity by reducing the growth thickness of silicon. Accordingly, the optimization of low thermal budget process may be expected.

Furthermore, the method of the present invention can minimize the amount of silicon source used for gap filling to form the silicon contact plug. Therefore, the method of the present invention is beneficial from economic and environment aspects.

In the drawings and specification, there have been disclosed typical preferred embodiments of the invention. Although specific terms are employed, they are used in a generic and descriptive sense only and not for purposes of limitation, the scope of the invention being set forth in, and being limited only by, the following claims.

What is claimed is:

1. A method for forming a contact plug of a semiconductor device, comprising the steps of:
forming an insulating layer on a silicon substrate;
forming a contact hole in the insulating layer;
forming an inorganic layer on a sidewall surface of the contact hole; and
forming a selective conductive plug in the contact hole including a surface of the inorganic layer.

2. The method of claim 1, wherein the inorganic layer includes an amorphous silicon layer or a complex of an oxide layer and a nitride layer.

3. The method of claim 1, wherein the step of forming the inorganic layer is performed with a SiH₄ flow rate of between 50 and 100 sccm, a N₂O flow rate of between 100 and 300 sccm, and a He flow rate of between 1000 and 3000 sccm.

4. The method of claim 1, wherein the step of forming the inorganic layer is performed with a pressure of between 1 and 10 Torr, a temperature of between 300 and 450° C., and a power of between 50 and 150 Watts.

5. The method of claim 1, wherein the inorganic layer is formed to a thickness of between about 10 Å and about 100 Å.

6. The method of claim 1, wherein the selective conductive plug includes a single crystalline silicon selectively grown on the surface of the silicon substrate and a polycrystalline silicon selectively grown on the inorganic layer.

7. The method of claim 6, wherein the step of forming the selective conductive plug is performed by means of a low-pressure chemical vapor deposition (LPCVD) process or an ultrahigh vacuum-chemical vapor deposition (UHV-CVD) process.

8. The method of claim 1, further comprising the steps of:
forming a gate structure on the silicon substrate before the step of forming the insulating layer; and then forming an insulating spacer on the gate structure.

9. The method of claim 8, wherein the step of forming the inorganic layer on the sidewall surface of the contact hole includes depositing the inorganic layer over an entire resultant structure having the contact hole, depositing an oxide layer over the inorganic layer, and selectively removing the oxide layer to retain only the inorganic layer lying on the gate structure, thus exposing the inorganic layer on the sidewall surface of the contact hole and further exposing the silicon substrate in the bottom surface of the contact hole.

10. The method of claim 9, wherein the oxide layer includes a plasma enhanced undoped silicate glass (PE-USG) layer.

11. The method of claim 10, wherein the step of depositing the PE-USG layer is performed with a SiH₄ flow rate of between 10 and 200 sccm, a N₂O flow rate of between 100 and 3000 sccm, a O₂ flow rate of 100 and 3000 between sccm, a He flow rate of up to 1000 sccm, a pressure of between 0.1 and 100 Torr, a temperature of between 350 and 600° C., and a power of between 100 and 1000 Watts.

12. The method of claim 10, wherein the PE-USG oxide layer has a thickness of between about 300 and about 1000 Å and step coverage is less than 50%.

13. The method of claim 9, wherein the step of selectively removing the oxide layer to retain only the inorganic layer lying on the gate structure is performed by sequentially using a reactive ion etching (RIE) process and a wet etching process.

14. The method of claim 13, wherein the RIE process is performed by using NF₃, O₂ and He gas plasma under a NF₃ flow rate of between 10 and 50 sccm, an O₂ flow rate of between 30 and 300 sccm, a He flow rate of between 100 and 2000 sccm, a pressure of between 1 mTorr and 10 Torr, a temperature ranging from between room temperature and 200° C., and a power of between 1 and 200 Watts.

15. The method of claim 13, wherein the wet etching process is performed by using a HF solution diluted with deionized water to a dilution level of between 50 and 500 times at a temperature of between 50 and 100° C.

16. The method of claim 14, wherein the RIE process is performed by using NF₃, O₂ and He gas plasma under a NF₃ flow rate of between 10 and 50 sccm, an O₂ flow rate of between 30 and 300 sccm, a He flow rate of between 100 and 2000 sccm, a pressure of between 1 mTorr and 10 Torr, a temperature ranging from between room temperature to 200° C., and a power of between 1 and 200 Watts.

17. The method of claim 13, further comprising the step of:
performing an in-situ cleaning process subsequent to the RIE process and to the wet etching process.

18. The method of claim 17, wherein the in-situ cleaning process is performed in the same chamber as the formation of the selective conductive plug.

19. The method of claim 17, wherein the in-situ cleaning process is performed by using a rapid thermal processing (RTP) or a hydrogen baking process.

20. The method of claim 19, wherein the hydrogen baking process is performed in between 5 and 30 minutes under a hydrogen flow rate of between 5 and 150 slm, a pressure of between 1 and 200 Torr, and a temperature of between 750 and 950° C.

21. The method of claim 19, wherein the in-situ cleaning process is performed by using the RTP in which the temperature rises to approximately 950° C. at a ramping rate of between 10 and 100° C./second.

22. The method of claim 6, wherein the step of forming the selective conductive plug uses a DCS-H₂—HCl gas system which is performed under a temperature of between 750 and 950° C., a pressure of between 5 and 150 Torr, a DCS flow rate of between 0.1 and 1 slm, a HCl flow rate of between 0.1 and 1 slm, and a H₂ flow rate of between 30 and 150 slm.

23. The method of claim 6, wherein the step of forming the selective conductive plug uses a MS-H₂—HCl gas system which is performed under a temperature of between 750 and 950°, a pressure of between 5 and 150 Torr, a MS (monosilane) flow rate of between 0.1 and 1 slm, a HCl flow rate of between 0.5 and 5 slm, and a H₂ flow rate of between 30 and 150 slm.

24. The method of claim 6, wherein the step of forming the selective conductive plug uses a Si₂H₆—Cl₂—H₂ gas system which is performed under a Si₂H₆ flow rate of between 1 and 10 sccm, a Cl₂ flow rate of up to 5 sccm, a H₂ flow rate of up to 20 sccm, and a temperature of between 600 and 800° C.

25. The method of claim 6, wherein the step of forming the selective conductive plug is performed under in-situ doping conditions by using H₂ gas including between 1 and 10% PH₃ gas.

26. The method of claim 25, wherein the step of forming the selective conductive plug is performed by adding GeH₄ with a flow rate of up to 10 sccm.

27. The method of claim 6, wherein the step of forming the selective conductive plug is carried out by using an ultrahigh vacuum-chemical vapor deposition (UHV-CVD) apparatus for single wafer processing or a tube type UHV-CVD apparatus for silicon epitaxial growth.
